(19) United States
(12) Patent Application Publication
(10) Pub. No.: US 2025/0157971 A1
(43) Pub. Date: May 15, 2025

(54) THREE-DIMENSIONAL CHIP STACK PREPARING METHOD AND THREE-DIMENSIONAL CHIP STACKING STRUCTURE

(71) Applicant: INSTITUTE OF SEMICONDUCTORS, GUANGDONG ACADEMY OF SCIENCES, Guangzhou (CN)

(72) Inventors: Chuan HU, Guangzhou (CN); Xun XIANG, Guangzhou (CN); Yingqiang YAN, Guangzhou (CN); Zhitao CHEN, Guangzhou (CN)

(21) Appl. No.: 18/944,701

(22) Filed: Nov. 12, 2024

(30) Foreign Application Priority Data
Nov. 14, 2023 (CN) 202311517268.8

(51) Int. Cl. H01L 23/00; H01L 25/065

(52) U.S. Cl. CPC H01L 24/14; H01L 24/11; H01L 24/13; H01L 24/16; H01L 24/27; H01L 24/29; H01L 24/32; H01L 24/33; H01L 24/73; H01L 24/81; H01L 24/83; H01L 24/92; H01L 25/0657; H01L 2224/11462; H01L 2224/1147; H01L 2224/13019; H01L 2224/13082; H01L 2224/13105; H01L 2224/13109; H01L 2224/13111; H01L 2224/13139; H01L 2224/13144; H01L 2224/13147; H01L 2224/13155; H01L 2224/1357; H01L 2224/13639; H01L 2224/13644; H01L 2224/13655; H01L 2224/13664; H01L 2224/14051; H01L 2224/14181; H01L 2224/16146; H01L 2224/27618; H01L 2224/2919; H01L 2224/32145; H01L 2224/33181; H01L 2224/73204; H01L 2224/8109; H01L 2224/81193; H01L 2224/81203; H01L 2224/83862; H01L 2224/92125; H01L 2225/06513; H01L 2225/06541; H01L 2225/06565

(57) ABSTRACT

The present invention discloses a three-dimensional chip stacking structure and preparing method, the method comprises: preparing a semi-cured organic film at a first surface and/or a second surface of a chip, and opening a window on the semi-cured organic film to expose the first conductive structure and/or the second conductive structure; completing a multi-layer chip stack by sequentially fixing the first conductive structure of an upper-layer chip to prickles of the second conductive structure of a lower-layer chip at a lower temperature; applying pressure to a top portion of the stacked multi-layer chip, and immersing a side wall of the metal bump and the prickles of the second conductive structure of the lower-layer chip in the first conductive structure of the upper-layer chip of the stacked multi-layer chip by means of a vacuum reflow process; heating the organic film to fully cure the organic film.

### CROSS REFERENCE TO RELATED APPLICATION

This application claims the priority of Chinese patent application No. 202311517268.8, filed on Nov. 14, 2024, which application is hereby incorporated herein by reference.

### FIELD OF THE INVENTION

The present invention relates to a technical field of integrated circuit packaging, and more particularly relates to a three-dimensional chip stack preparing method, and a three-dimensional chip stacking structure.

### BACKGROUND OF THE INVENTION

With development of technologies such as artificial intelligence, smart driving, and high-performance computing, a higher demand for storage technology has been put forward, and it is necessary to develop a higher bandwidth and larger capacity storage technology. To meet the demand of higher bandwidth and larger capacity storage technology, the advanced packaging technology receives more and more widespread attention. At present, the more mainstream advanced packaging mainly includes fan-out wafer-level packaging (FO), wafer-level chip scale packaging (WLCSP), 2.5D/3D packaging and system-in-package (SiP), wherein the three-dimensional chip stacking packaging is an IC packaging method that places a complete computer chip (e.g., dynamic random access memory) on the top of another chip (e.g., central processing unit), it relies on metalized interconnection structures between silicon layers to realize an electrical connection between the corresponding chips. Since multiple dies or substrates can be directly stacked together by bonding to realize a metal interconnection structure in three-dimensional directions, the three-dimensional chip stacking structure can greatly reduce the interconnecting distance between the chips, thereby increasing the data transfer rate and bandwidth, reducing latency and power consumption and increasing storage capacity. As a result, the three-dimensional chip stacking packaging has become an effective solution to develop high-performance memories.

For the three-dimensional chip stacking packaging technology, interlayer bonding is one the core technology of three-dimensional stacking technology. At present, the industry usually adapts methods such as thermocompression bonding and reflow soldering chip bonding to realize the interlayer bonding of a three-dimensional stack. Among them, the thermocompression bonding usually requires a higher pressure and a higher temperature, and is usually in the form of die to chip (aka chip-level stacking) so that the difficulty of the process is greater, and has low packaging efficiency since the thermocompression bonding needs to perform interlayer bonding layer by layer. In addition, the technology uses NCF or NCP, however, NCF or NCP are easily to remain between the upper-layer and lower-layer solder after use, which can easily cause breakage and seriously affect the reliability of the interconnection of solder between the chips. The chip three-dimensional stacks that adapt reflow soldering are usually in the form of wafer to wafer (aka wafer-level stacking). The technology is performed by stacking a great number of chips by solder, then heating and reflowing the solder to realize the effective bonding between upper layer and lower layer, and finally, using the bottom filling and plastic sealing process to realize filling of solder gap and plastic sealing protection of the area around the chip. Because of mass reflow bonding and wafer-level stacking of the chip, the technology has high packaging efficiency, but the technology has at least the following key flaws that need to be solved:
1. The technology is performed by bonding the solder, and then filling the gap of the solder with insulating material for the process route, and it causes the solder easy to diffuse and connect to each other during the heat reflow process, causing a short circuit, which would have negative effects on the pin size and spacing;
2. The technology is performed by underfilling the solder gap at the end of the packaging process, and the very limited space of the multi-layer stack structure and between layers make underfilling very difficult; and
3. During the reflow soldering process, the chip and the wafer would warp and deform so that the bonding yield of the chip would decrease.

### SUMMARY OF THE INVENTION

An embodiment of the present invention provides a three-dimensional chip stack preparing method to solve at least one existing technical problem when performing interlayer bonding of three-dimensional chip stacking structure by means of reflow bonding.

In a first aspect, an embodiment of the present invention provides a three-dimensional chip stack preparing method, comprising:
forming a conductive structure at a first surface and a second surface of a chip prepared with a metal filling TSV and a redistribution layer; wherein the conductive structure comprises a first conductive structure at the first surface of the chip and a second conductive structure at the second surface of the chip, the second conductive structure is a metal bump having prickles;
preparing a semi-cured organic film at the first surface and/or the second surface of the chip, and opening a window on the semi-cured organic film to expose the first conductive structure and/or the second conductive structure;
completing a multi-layer chip stack by sequentially fixing the first conductive structure of an upper-layer chip to the prickles of the second conductive structure of a lower-layer chip at a lower temperature;
applying pressure to a top portion of the stacked multi-layer chip, and immersing a side wall of the metal bump and the prickles of the second conductive structure together with the first conductive structure, by means of a vacuum reflow process, to realize a complete bonding of the first conductive structure and the second conductive structure, wherein the second conductive structure is in the lower-layer chip and the first conductive structure is in the upper-layer chip of the stacked multi-layer chip, and adhering the upper-layer and lower-layer chips by the semi-cured organic film; and
heating the organic film to fully cure the organic film to form a three-dimensional chip stacking structure.

In a second aspect, a use of the three-dimensional chip stack preparing method of the first aspect of the present invention on the chip-level stack or a wafer-level stack is provided.

In a third aspect, an embodiment of the present invention provides a three-dimensional chip stacking structure, comprising:
a substrate;
at least two chip layers provided on the substrate, each of the chip layers comprising at least one chip;
at least two bonding structures provided between the adjacent chip layers, wherein the boding structures are formed by bonding a first conductive structure of a first surface of the chip in the upper-layer chip and a second conductive structure of a second surface of the chip in the lower-layer chip, the second conductive structure is a metal bump having prickles;
an organic film provided between the adjacent chip layers for adhering the adjacent chip layers, the organic film isolating the adjacent bonding structures from each other, wherein a organic isolation film is formed by heating the semi-cured organic film to fully cure; and
a TSV penetrating the chip in the chip layer, the first surface and the second surface of each chip being connected by the TSV penetrating the chip.

In a fourth aspect, an embodiment of the present invention provides a three-dimensional chip stacking structure manufactured by the method of the first aspect.

The advantageous effects of the embodiments of the present invention are that: in the solution provided by the embodiments of the present invention, the conductive structures are prepared on both the first surface and the second surface of the chip, and the second conductive structure on the second surface is a metal bump having prickles, the first conductive structures can be fixed on the metal bump just by a pick-and-place process, and thus enables a large number of upper-layer chips and lower-layer chips to be accurately and quickly batch temporarily bonded at a lower temperature, thereby enabling mass reflow processes to be performed on the batch temporarily bonded stacked multi-layer chip, to realize rapid stacking and packaging of chips and significantly reduce packaging costs. Moreover, the solution of the embodiment of the present invention completes the stacking of the insulating structure while the chips are stacked, which makes filling the gap between the upper-layer and lower-layer chips extremely simple. Meanwhile, since the organic film prepared in the embodiment of the present invention is cured after the reflow process, and has been in a semi-cured state with certain fluidity before that. Therefore, the embodiment of the present invention has lower requirements on the height consistency of the conductive structures, that is, the first conductive structures and the metal bumps having prickles, and the process window is larger. In addition, the insulating structure of the example of the present invention uses an organic film to isolate the conductive structures to prevent short circuit of the conductive structures. The organic film is very easy to be cleaned and does not cause the problem of residue. Therefore, the solution of the example of the present invention can also greatly improve the reliability of the prepared three-dimensional stack packaging structure. Finally, the upper-layer and lower-layer wafers/chips in the embodiment of the present invention are adhered to each other by the organic film. That is, the organic film not only blocks the short circuit of the conductive structures, but also acts as an adhering layer between the upper and lower layers. This adhering method avoids the higher temperature requirements for interlayer bonding, and thus also avoids the thermal stresses and other damages to the packaging structure brought about by higher temperature processes such as thermocompression, which can effectively improve the reliability of the prepared three-dimensional stacked packaging structure, and effectively reduces the process difficulty of interconnecting the upper-layer and lower-layer chips in the prior art (that is, the adhering can be realized just by the reflow process and curing), thereby further reducing the process cost of three-dimensional stack packaging. Since the three-dimensional stacked packaging structure prepared by embodiments of the present invention has higher reliability, lower process difficulty and lower process cost, it can be widely used in the manufacture of high-performance memories, high-capacity memories, high-bandwidth memories, etc.

### BRIEF DESCRIPTION OF THE DRAWINGS

In order to more clearly illustrate the technical solutions of the embodiments of the present invention, drawings needed to be used in the description of the embodiments will be briefly described below. Obviously, the drawings in the following description are some examples of the present invention. For a person having ordinary skill in the art, other drawings can be obtained based on these drawings without exerting creative efforts.

FIG. 1 schematically illustrates a flowchart of a three-dimensional chip stack preparing method according to an embodiment of the present invention;

FIG. 2 schematically illustrates a flowchart of a preparing method of first conductive structures according to an embodiment of the present invention;

FIG. 3 schematically illustrates a vertical cross-sectional view of a chip structure formed during the preparation of the first conductive structures according to an embodiment of the present invention;

FIG. 4 schematically illustrates a vertical cross-sectional view of a chip structure formed during the preparation of the first conductive structures according to an embodiment of the present invention;

FIG. 5 schematically illustrates a vertical cross-sectional view of a chip structure formed during the preparation of the first conductive structures according to an embodiment of the present invention;

FIG. 6 schematically illustrates a vertical cross-sectional view of the chip structure formed during the preparation of the second conductive structures according to an embodiment of the present invention;

FIG. 7 schematically illustrates a vertical cross-sectional view of a chip structure formed during the preparation of the second conductive structures according to an embodiment of the present invention;

FIG. 8 schematically illustrates a vertical cross-sectional view of the structure obtained during the preparing process of example 1 of an embodiment of the present invention;

FIG. 9 schematically illustrates a vertical cross-sectional view of the structure obtained during the preparing process of example 1 of an embodiment of the present invention;

FIG. 10 schematically illustrates a vertical cross-sectional view of the structure obtained during the preparing process of example 1 of an embodiment of the present invention;

FIG. 11 schematically illustrates a vertical cross-sectional view of the structure obtained during the preparing process of example 1 of an embodiment of the present invention;

FIG. 12 schematically illustrates a vertical cross-sectional view of the structure obtained during the preparing process of example 1 of an embodiment of the present invention;

FIG. 13 schematically illustrates a vertical cross-sectional view of the structure obtained during the preparing process of example 1 of an embodiment of the present invention;

FIG. 14 schematically illustrates a vertical cross-sectional view of the structure obtained during the preparing process of example 1 of an embodiment of the present invention;

FIG. 15 schematically illustrates a vertical cross-sectional view of the structure obtained during the preparing process of example 1 of an embodiment of the present invention;

FIG. 16 schematically illustrates a vertical cross-sectional view of the structure obtained during the preparing process of example 1 of an embodiment of the present invention;

FIG. 17 schematically illustrates a vertical cross-sectional view of the structure obtained during the preparing process of example 1 of an embodiment of the present invention;

FIG. 18 schematically illustrates a vertical cross-sectional view of the structure obtained during the preparing process of example 2 of an embodiment of the present invention;

FIG. 19 schematically illustrates a vertical cross-sectional view of the structure obtained during the preparing process of example 2 of an embodiment of the present invention;

FIG. 20 schematically illustrates a vertical cross-sectional view of the structure obtained during the preparing process of example 3 of an embodiment of the present invention;

FIG. 21 schematically illustrates a vertical cross-sectional view of the structure obtained during the preparing process of example 3 of an embodiment of the present invention; and

FIG. 22 schematically illustrates a vertical cross-sectional view of a three-dimensional chip stacking structure in some embodiments.

### DETAILED DESCRIPTION OF THE PREFERRED EMBODIMENTS

In order to make the purpose, technical solutions and advantages of the embodiments of the present invention clearer, the technical solutions in the embodiments of the present invention will be clearly and completely described below in conjunction with the drawings in the embodiments of the present invention. Obviously, the described embodiments are part of the embodiments of the present invention rather than all of the embodiments. Based on the embodiments of the present invention, all other embodiments obtained by a person having ordinary skill in the art without creative efforts fall within the scope of protection of the present invention.

It should be noted that, as long as there is no conflict, the embodiments and features in the embodiments of the present application can be combined with each other.

It should also be noted that the terms used in the present application are typically terms commonly used by a person having ordinary skill in the art. If they are inconsistent with commonly used terms, the terms in the present application shall prevail.

For a person having ordinary skill in the art, the specific meanings in the present invention of the terms in the present application can be understood according to specific circumstances.

Finally, it should be noted that in the context, relational terms such as first and second are only used to distinguish one entity or operation from another entity or operation, and do not necessarily require or imply that these entities or these operations have any such actual relationship or sequence between them. It should be understood that the terms used in this way are interchangeable under appropriate circumstances. This is merely a way of distinguishing objects with the same attributes in the description of the embodiments of the present application. Furthermore, the terms “includes” and “comprises” include not only those elements but also other elements not expressly listed or elements inherent to such process, method, article or apparatus. Without further limitation, an element defined by the statement “comprising . . . ” does not exclude the presence of additional identical elements in a process, method, item, or device that includes the stated element.

In the context, the term “chip” refers to any type of semiconductor chip or integrated circuit chip or semiconductor die or integrated circuit die that has been cut from a wafer and realizes a specific function, and it also refers to any type of semiconductor chip or integrated circuit chip that remains on a wafer and realizes a specific function.

In the context, the term “chip-level stack” refers to a stacking form of die to wafer, which refers to chips or dies that meet specific functions and are cut from the wafer and bonded together through three-dimensional chip stacking packaging technology to form a three-dimensional chip stacking structure.

In the context, the term “wafer-level stack” is a stacking form of wafer to wafer, which refers to a stack packaging process for forming a three-dimensional chip stacking structure by bonding an entire wafer of one type over an entire wafer with an entire wafer of another type through the three-dimensional chip stacking packaging technology while the chip is still on the wafer.

Three-dimensional chip stacking packaging technology realizes the metal interconnection structure of the chips in the three-dimensional direction by stacking multiple dies or substrates through bonding, greatly reducing the interconnecting distance between the chips and effectively reducing delays and power consumption, improving the bandwidth of data transmission, increasing storage capacity, and providing an effective solution for the development of high-performance memory. However, the existing three-dimensional chip stacking packaging process often has problems when interconnecting upper-layer and lower-layer chips, such as difficult alignment, prone to thermal stress problems at high temperatures, complex process flow, and low yield. These problems severely limit the application of the three-dimensional chip stacking packaging in the preparation of high-capacity and high-bandwidth memories. An example of the present invention provide a three-dimensional chip stack preparing method based on a reflow soldering process, which enables all chip layers to be stacked and packaged together to be quickly and accurately temporarily bonded at a lower temperature, and after the temporary bonding, all chip layers can be completely bonded together through a mass reflow process, which greatly reduces the packaging cost of three-dimensional chip stacking and process difficulty of interconnecting upper-layer and lower-layer chips in the prior art, and the solution provided by the examples of the present invention is to prepare an insulating structure before mass reflow, that is, the stacking of the insulating structure is completed while stacking the chips. Therefore, the requirement for height consistency of the conductive structures is lower and the preparation of the insulating structure is much less difficult, and the yield and reliability of the prepared three-dimensional chip packaging structure is effectively improved, and it can be applied to the preparation of high-performance memories. In particular, it should be noted that the lower temperature in the examples of the present invention means lower than the melting point of the material of the first conductive structures. In practical, the specific temperature corresponding to the lower temperature can be determined based on the material of the first conductive structures. Taking the first conductive structures as solder as an example, the lower temperature may refer to the temperature lower than the melting point of the solder. When the first conductive structure is made of other materials, the lower temperature refers to the temperature lower than the melting point of the corresponding material. Of course, in some cases, the lower temperature can also refer to room temperature.

The solutions of the examples of the present invention will be described in detail below with reference to the accompanying drawings.

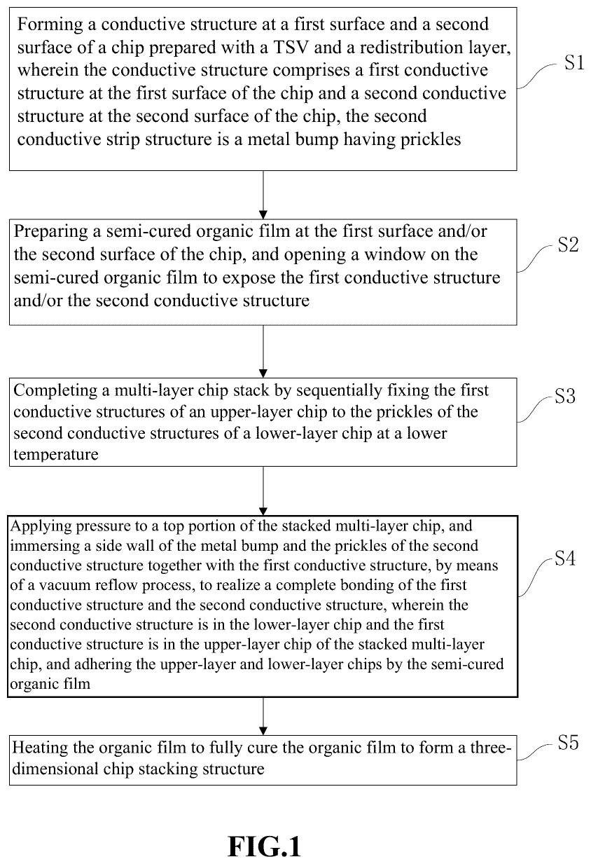

FIG. 1 schematically illustrates the process of a three-dimensional chip stack preparing method according to an embodiment of the present invention. As shown in FIG. 1, it can be realized by including:
Operation S1: forming conductive structures at a first surface and a second surface of a chip prepared with a TSV and a redistribution layer, wherein the conductive structures comprise first conductive structures at the first surface of the chip and second conductive structures located at the second surface of the chip, the second conductive structures are metal bumps having prickles;
Operation S2: preparing a semi-cured organic film at the first surface and/or the second surface of the chip, and a window is opened on the semi-cured organic film to expose the first conductive structures and/or the second conductive structures;
Operation S3: completing a multi-layer chip stack by sequentially fixing the first conductive structures of an upper-layer chip to the prickles of the second conductive structures of a lower-layer chip at a lower temperature;
Operation S4: applying pressure to a top portion of the stacked multi-layer chip, and immersing side walls of the metal bumps and the prickles of the second conductive structures together with the first conductive structures, by means of a vacuum reflow process, to realize a complete bonding of the first conductive structures and the second conductive structures, wherein the second conductive structures are in the lower-layer chip and the first conductive structures are in the upper-layer chip of the stacked multi-layer chip, and adhering the upper-layer and lower-layer chips by the semi-cured organic film; and
Operation S5: heating the organic film to fully cure the organic film to form a three-dimensional chip stacking structure.

In the operation S1, the first surface specifically refers to a surface of the chip on which a pin layer is formed, and the prepared first conductive structures are specifically formed on the pin layer. The second surface specifically refers to another surface of the chip opposite to the surface on which the pin layer is formed. A redistribution layer is generally prepared on this surface, and the second conductive structures are specifically formed on the redistribution layer on the second surface. Of course, in some embodiments, the redistribution layer can also be prepared on the first surface where the pin layer is located according to the needs. Before the operating S1, the pin layer and the redistribution layer can be prepared by corresponding process flows. These process flows include but are not limited to preparing TSVs in the chip and performing metal filling, preparing the redistribution layer, which is conductive to the TSVs, on the second surface of the chip, and preparing the pin layer, which is conductive to the TSVs, on the first surface of the chip. These process flows can be prepared according to the existing process according to the needs, so they will not be repeated here.

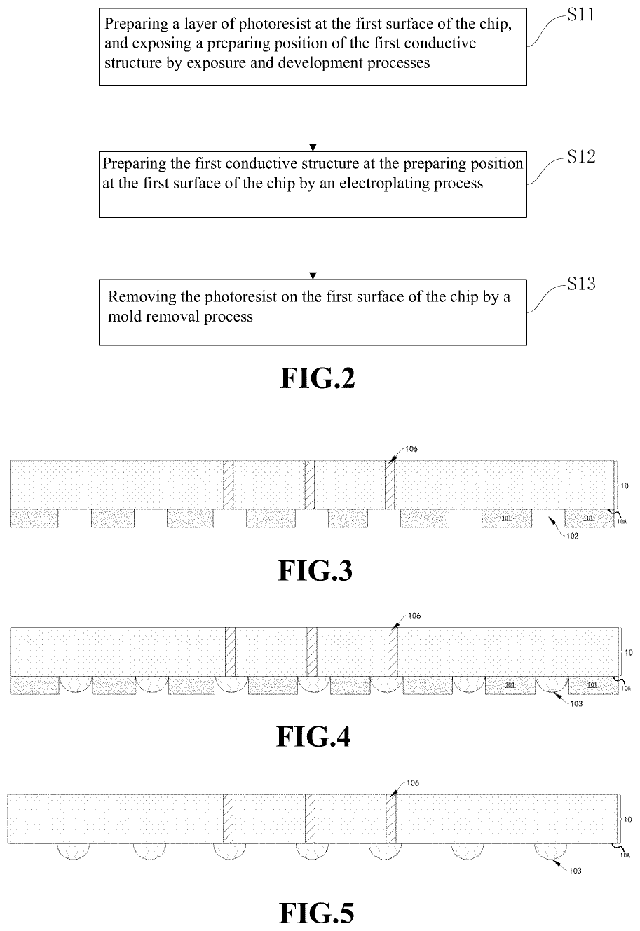

The preparing process of the first conductive structures will be described in detail below with reference to FIGS. 2 to 5. Among them, FIG. 2 schematically illustrates the preparing process of the first conductive structures. As shown in FIG. 2, it can be implemented by including:
Operation S11: preparing a layer of photoresist at the first surface of the chip, and exposing preparing positions of the first conductive structures by exposure and development processes. Taking the first conductive structures as solder balls as an example, a vertical cross-sectional sectional view of the formed chip structure is shown in FIG. 3, and solder ball preparing locations 102 separated by photoresist 101 are formed on the first surface 10A of the chip 10, wherein the solder ball preparing positions and their number can be specifically designed according to the needs.
Operation S12: preparing the first conductive structures at the preparing positions at the first surface of the chip by an electroplating process. Taking the first conductive structures as solder balls as an example, a vertical cross-sectional view of the formed chip structure is shown in FIG. 4, and the solder balls 103 are prepared and formed at the solder ball preparing positions 102.
Operation S13: removing the photoresist on the first surface of the chip by a PR striping process. Taking the first conductive structures as solder balls as an example, the vertical cross-sectional view of the formed chip structure is shown in FIG. 5, the photoresist 101 on the first surface is fully removed, and solder balls 103 are formed only at the corresponding preparing positions. These solder balls 103 are the first conductive structures formed on the first surface.

In some possible embodiments, the material of the first conductive structures may be soft gold, indium, gallium, tin, tin-silver, tin-gold, other metals or alloys of the above material. Using soft metals or alloys to prepare the first conductive structures makes it easier for the first conductive structures to be inserted and fixed on the prickles of the second conductive structures, and it is easier to realize temporary bonding between the chips.

In other possible embodiments, the material of the first conductive structures may be nano-scale to micron-scale solder. In other possible embodiments, the material of the first conductive structures may be nano-scale to micron-scale linear or granular conductive porous dielectric materials of metals such as copper, silver, gold, and tin. Using this kind of metals or alloys to prepare the first conductive structures makes it easier for the first conductive structures to be inserted and fixed on the prickles of the second conductive structures, and it is easier to realize temporary bonding between chips.

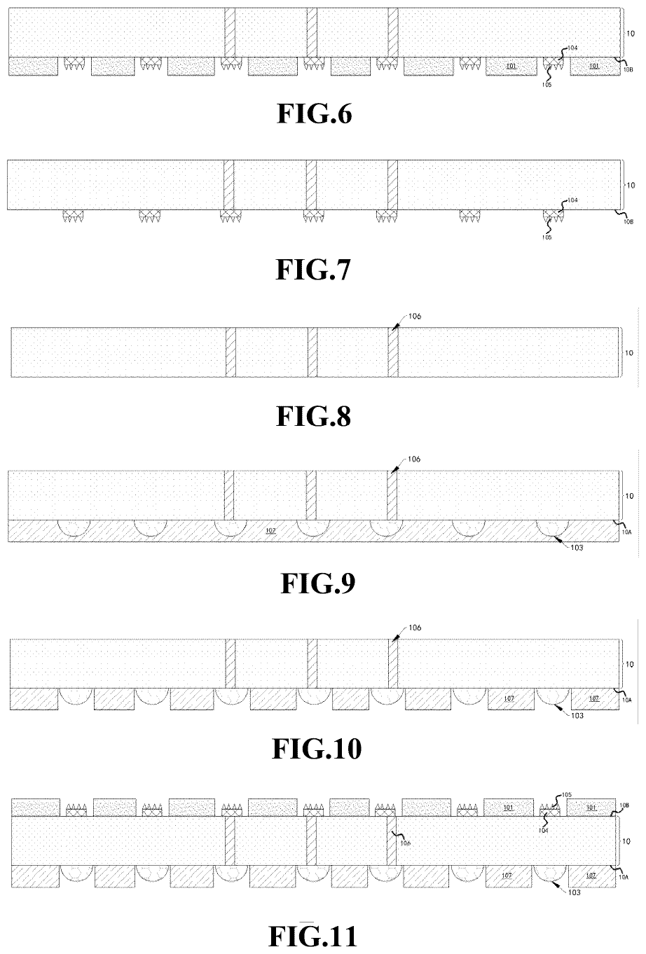

More preferably, nano-scale particles or mixed nano-scale and micro-scale particles also have the characteristic of low melting point (nanoparticles have low melting point). Using materials with such characteristic to prepare the first conductive structures also makes it easier for the first conductive structures to realize complete bonding with the second conductive structures during reflow soldering, and further reduces the implement difficulty of interlayer bonding process. The preparing process of the second conductive structures is similar to the process of preparing the first conductive structures. It is also necessary to first prepare a layer of photoresist at the first surface of the chip, and then expose the preparing positions of the second conductive structures through exposure and development processes. The difference is that after the preparing positions of the second conductive structures are exposed, the metal bumps and the prickles on the metal bumps are prepared at corresponding positions on the second surface of the chip through processes such as electroplating or chemical plating. The vertical cross-sectional view of the formed chip structure is shown in FIG. 6. The formed second conductive structures include the metal bumps 104 and the prickles 105 on the metal bumps 104. The second conductive structures are separated by the photoresist 101 on the second surface 10B. After that, similar to the preparing process of the first conductive structures, it is also necessary to remove the photoresist on the second surface 10B of the chip by the PR striping process. The vertical cross-sectional view of the thus formed chip structure is shown in FIG. 7.

It should be noted that when forming the conductive structures, the first conductive structures can be prepared first, or the second conductive structures can be prepared first, and when preparing the second conductive structures, the prickles on the metal bumps can be prepared at the same time as the metal bumps, or the prickles on the metal bumps can be prepared after preparing the metal bumps. The examples of the present invention are not limited to the order. It should also be noted that for the same chip, after the processing of operation S1, the chip structure obtained has conductive structures formed on both the first surface and the second surface. For example, as shown in FIG. 11, the first conductive structures, which are the solder balls 103, are formed on the first surface 10A of the chip structure obtained, and the second conductive structures, which are the metal bumps 104 having prickles 105, are formed at the second surface.

Among them, the prickles and metal bumps in the second conductive structures can be made of different materials or can be made of the same material, which is not limited in the examples of the present invention. In some possible embodiments, the material of the metal bumps of the second conductive structures is metals such as copper, nickel, gold, silver, or alloys of the above material, and the material of the prickles of the second conductive structures is selected from metals such as nickel, copper, gold, or silver. In other embodiments, the material of the second conductive structures can also be selected from other metals or alloys as long as its hardness is higher than that of the first conductive structures, so that it is easier for the first conductive structures to be inserted and fixed on the prickles of the second conductive structures, and it is easier to realize temporary bonding between the chips. It should be noted that when the metal bumps and the prickles of the second conductive structures are made of the same material, it is preferably considered to prepare the metal bumps and the prickles at one time. For example, taking the material of metal bumps and prickles to be copper, the metal bumps and prickles can be prepared at one time by electroplating. In this case, the prepared metal bumps refer to the relatively neat metal layer at the bottom, and the prickles refer to the metal structures protruding from the surface of the relatively neat metal layer.

As a possible embodiment, the height of the metal bumps is between 0.5 μm and 50 μm, and the height of the prickles is between 0.05 μm and 10 μm.

In a preferred embodiment, the surface and the side walls of the metal bumps can be further prepared with a metal protective film. The metal used in the metal protective film can be metals such as silver, gold, nickel, or palladium. Preferably, the metal used in the metal protective film is different from the material of the metal bumps. By preparing a layer of metal protective film on the surface and the side walls of the metal bumps, the metal bumps can be protected during the three-dimensional stack packaging process so as to effectively prevent the metal bumps from oxidizing and improve the reliability of the prepared three-dimensional stacking structure.

As a possible embodiment, the prickles on the metal bumps of the second conductive structures are formed by chemical or physical deposition. In a preferred embodiment, the surface of the prickles can also be plated with a passivation layer of inert metal such as palladium or gold to protect the prickles and prevent them from oxidizing.

In actual operation, the metal protective film of the metal bumps and the inert metal passivation layer of the prickles can be prepared together or separately, and they can be made of exactly the same material or different materials. Taking the metal bumps as copper metal bumps, the protruding material as copper, and the metal protective film and the inert metal passivation layer both as palladium as an example, nano-copper wires can be prepared on the copper metal bumps by electroplating, and then a layer of palladium or gold is electroplated on the copper wires and copper metal surfaces and side walls, and then a passivation treatment is performed to prepare and form the second conductive structures with the metal protective film and the inert metal passivation layer.

As a preferred embodiment, the prickles can be formed as metallic linear, rod-shaped, cone or other shaped clusters, and a diameter of the smallest unit forming the cluster is nano-scale to micron-scale. Preparing the prickles into such structure enables the prickles to be better inserted into the first conductive structures during the temporary bonding process, thereby having a stable fixing effect, and improving the bonding effect of the temporary bonding. It should be noted that the cluster is an aggregation of smaller particles. The diameter of the smallest unit constituting the cluster being in the nano-scale to micron-scale, means that the diameter of these smaller particles is nano-scale to micron-scale.

As shown in FIGS. 5 and 7, the formed first conductive structures and the second conductive structures are arranged at intervals, that is, there are gaps between the adjacent first conductive structures and second conductive structures. As a preferred embodiment, in order to realize insulation isolation between the first conductive structures to prevent short circuit of the conductive structures, and also to realize tight combination between the adjacent chip layers, in an embodiment of the present invention, an organic film filled at the gap of the first conductive structures and/or the second conductive structures is prepared on the first surface and/or the second surface of the chip to realize isolation between structures by the filled organic film, thereby preventing the occurrence of short circuits while realizing tight adhering and solid combining between the upper-layer and lower-layer chips. Using the organic film as an insulating structure not only enables isolation between the conductive structures, but also enables the bonding between upper-layer and lower-layer chips to be realized through the organic film because the organic film prepared in the embodiment of the present invention is in a semi-cured state. Compared with inorganic insulating materials such as silicon dioxide, the insulating structure of the examples of the present invention enables adhesion between the upper-layer and lower-layer chips during the vacuum reflow process, and the bonding between the insulating structure can be accomplished after the vacuum reflow process just by heating and curing, and the difficulty of the bonding is much lower than that of the inorganic insulating materials, which also enables the preparation and stacking of insulating structures prior to the reflow process in the embodiment of the present invention. Compared with the traditional reflow process, the difficulty of preparing the insulating structure and the difficulty of bonding are greatly reduced, and because the insulating structure is prepared before the reflow process, and the insulating structure is an semi-cured organic film, the method of the embodiment of the present invention has low requirements for the conductive structures, especially the first conductive structures of height consistency, which further reduces the process difficulty and packaging cost of stacked packaging, and also avoids warping and improves the reliability of the prepared the reliability of the prepared three-dimensional stacked structure. In the operation S2, the organic film may be prepared only at the gap of the first conductive structures of the chip, or the organic film may be prepared only at the gap of the second conductive structures of the chip, or the organic film may be prepared both at the gap of the first conductive structures and the gap of the second conductive structures. The organic film may specifically be a negative photoresist. For example, the negative photoresist may be prepared by using a composite material or a single material such as polyimide, photoresist and epoxy by a dry film method or a coating method. Since the negative photoresist is very easy to be cleaned, it does not cause the problem of residue. Therefore, the solution of the embodiment of the present invention effectively avoids problems such as circuit breakage and reliability caused by the insulating material easily remaining between the upper-layer and lower-layer solder, and further improves the reliability of the prepared three-dimensional stacked structure. The specific method of preparing the organic film is to prepare a layer of negative photoresist in B-stage on the surface of the chip where the first conductive structures and/or the second conductive structures are formed, and then open a window on the negative photoresist in the B-stage by processes such as exposure and development to expose the conductive structures, i.e., the first conductive structure and/or the second conductive structure, on the corresponding surface, thereby allowing the organic film to fill the gap between the first conductive structures and/or the second conductive structures. Specifically, the thickness of the prepared organic film can be determined according to the height of the gap between the upper-layer and lower-layer chips, and can be, for example, between 2-50 μm. Preferably, the organic film prepared in the embodiment of the present invention is in a semi-cured state, wherein the semi-cured state preferably means that the organic film prepared through the operation S2 is in the B-stage and has certain fluidity. The semi-cured organic film allows the organic film in the embodiment of the present invention to not only serve as an insulating structure for isolating the conductive structures, but also to realize the adhering of the upper and lower chip layers. Meanwhile, since the organic film of the embodiment of the present invention prior to the reflow process has certain fluidity, the bonding requirements between the first conductive structures on the upper-layer chip and the metal bumps on the lower-layer chip, such as solder and metal bump height consistency, can also be reduced.

It should be noted that in a specific embodiment, the operation S2 is not limited to being performed after the operation S1, and it may be performed after preparing the corresponding conductive structures. For example, in the case of filling the gap of the first conductive structures with the organic film, a layer of negative photoresist is directly prepared on the first surface right after the first conductive structures are prepared and formed (such as after the operation S13), and then a window is opened on the semi-cured organic film by processes such as exposure and development to expose the first conductive structures to form an organic film filling the gaps between the first conductive structures; in the case of filling both the gaps of the first conductive structures and the second conductive structures with the organic film, the organic film filled between the gaps of the corresponding conductive structures can be prepared right after the preparing of the corresponding conductive structures, and then the preparing process of another conductive structure may be performed.

Since the second conductive structures of the embodiment of the present invention are the metal bumps with the prickles, in the operation S3, the first conductive structures of the stacked upper-layer chip can be fixed to the prickles of the second conductive structures of the lower-layer chip through a pick-and-place process to realize the temporary bonding between the chips under lower temperature conditions, which facilitates the rapid completion of the stacking of multi-layer chip. The process is simple and can effectively reduce the cost and the process difficulty of the interconnection between the chips, and since the high-temperature thermocompression is not required, it can also avoid damages to the stacking structure caused by thermal stresses, and improve the reliability and yield of the prepared three-dimensional chip stacked structure.

In specific applications, the operation of fixing the first conductive structures of the upper-layer chip on the prickles of the second conductive structures of the lower-layer chip can be repeated according to the number of chips to be stacked to complete the stacking of a multi-layer chip. In a preferred embodiment, before fixing the first conductive structures of the upper-layer chip on the prickles of the second conductive structures of the lower-layer chip, heated formic acid or the like can also be used to preprocess the upper-layer chip to be placed on the lower-layer chip to prevent the first conductive structures of the upper-layer chip and the second conductive structures of the lower-layer chip from oxidizing during fixation, and ensure the yield of the chip interconnection and the reliability of the prepared three-dimensional chip stacking structure. It should be noted that the pick-place process is an existing mature technology and can be performed with reference, so it will not be repeated here. It should also be noted that in the operation S3, the temporary bonding and stacking of all chip layers can be completed just by a pick-and-place process under lower temperature conditions, and since the semi-cured organic film has been pre-prepared in the operation S2, not only the temporary bonding and stacking of all chip layers is completed, but also the stacking of the insulating structures between all chip layers is completed by the operating S3, so that by the reflow process of the operating S4, the bonding of conductive structures and insulating structures between all layers of chips can be completed in batches, which greatly improves packaging efficiency and reducing packaging costs. In the operation S4, by performing a vacuum reflow process on the multi-layer-stack chip temporarily bonded and formed in the operation S3, the completely bonding of the conductive structures of the stacked multi-layer chip can be realized, and at the same time, the upper-layer and lower-layer chips can be adhered to each other by the organic film. Among them, in the preferred embodiment of the present invention, applying pressure to the top portion of the stacked multi-layer chip can effectively ensure the strength of the bonding between the upper-layer and lower-layer chips, thereby ensuring the long-term reliability of the prepared three-dimensional chip stacking structure.

Among them, the vacuum reflow process (also called vacuum reflow soldering process) is an existing mature technology. In the operation S4, the vacuum reflow process can be performed with reference to the existing technology to realize complete bonding of the first conductive structures and the metal bumps of the second conductive structures. By using the vacuum reflow process, the oxidation of the first conductive structures of the upper-layer chip and the second conductive structures of the lower-layer chip can be further avoided, thereby improving the packaging yield and the reliability of the prepared three-dimensional chip stacking structure.

In an example of the present invention, before the first conductive structures of the upper-layer chip and the metal bumps of the lower-layer chip are completely bonded by the vacuum reflow, the organic film is in B-stage and has certain fluidity (i.e., semi-cured state). Therefore, by applying pressure and performing vacuum reflow at the top portion in the operation S4, the organic film can sufficiently fills the gap between the upper-layer chip and the lower-layer chip and adheres the upper-layer chip and the lower-layer chip more closely, and then the organic film is further heated to cure by the operation S5, the complete bonding of the insulating structure can be completed, and the difficulty of the bonding process of the insulating structure can therefore be greatly reduced. Since the organic film using negative photoresist is easy to be cleaned, it can greatly improve the yield of the interconnection and reliability of the packaging structure. In particular, the first conductive structures and the second conductive structures can be completely immersed to realize complete bonding after vacuuming and reflow. In particular, the gap formed between the first conductive structures can be diffused and filled with the organic film to further improve and ensure the stability and yield of the chip interconnection.

It should be noted that in the case that the organic film is only prepared at the gap between the first conductive structures of the chip, the organic film is adhered to the second surface of the lower-layer chip after the vacuum reflow process in the operation S4 to realize the adhering of the adjacent layers of the chips; in the case that the organic film is only prepared at the gap between the second conductive structures of the chips, the organic film is adhered to the first surface of the upper-layer chip after the vacuum reflow to realize the adhering of the adjacent layers of the chips; and in the case that the organic film is prepared both at the gap between the first conductive structures and the gap between the second conductive structures, the organic film in the solder gap of the upper-layer chip and the organic film in the metal bump gap of the lower-layer chip are adhered to each other after vacuum reflow to realize the adhering of the adjacent layers of the chips. Based on this, when preparing the organic film, there are more process route choices (such as preparing the organic film only at the gap of the first conductive structures, or preparing the organic film only at the gap of the second conductive structures, etc.), and the process window is larger, and thus the difficulty of process preparation can be further reduced.

In specific applications, the above preparing method according to the embodiment of the present invention can be applied in either a chip-level stack packaging process or a wafer-level stack packaging process. In the case that it is applied in the chip-level stack packaging process, the wafer needs to be diced into independent chips before using the pick-and-place process for chip stacking. In the case that it is applied in the wafer-level stack packaging process, the dicing process can be performed after the operation S5.

Taking the first conductive structures as solder as an example, the process of preparing a three-dimensional chip stacking structure using the above three-dimensional chip stack preparing method will be exemplified below through three specific examples.

### Example 1

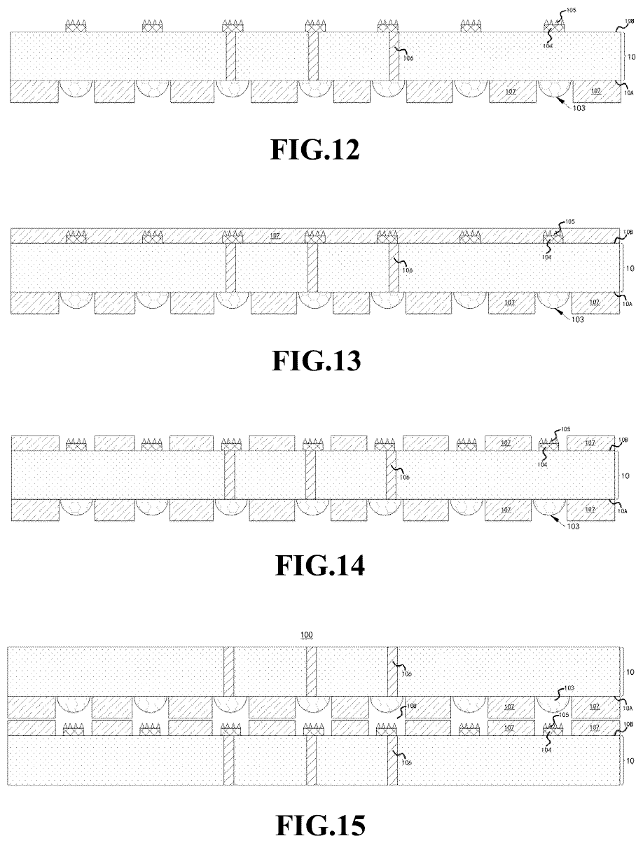

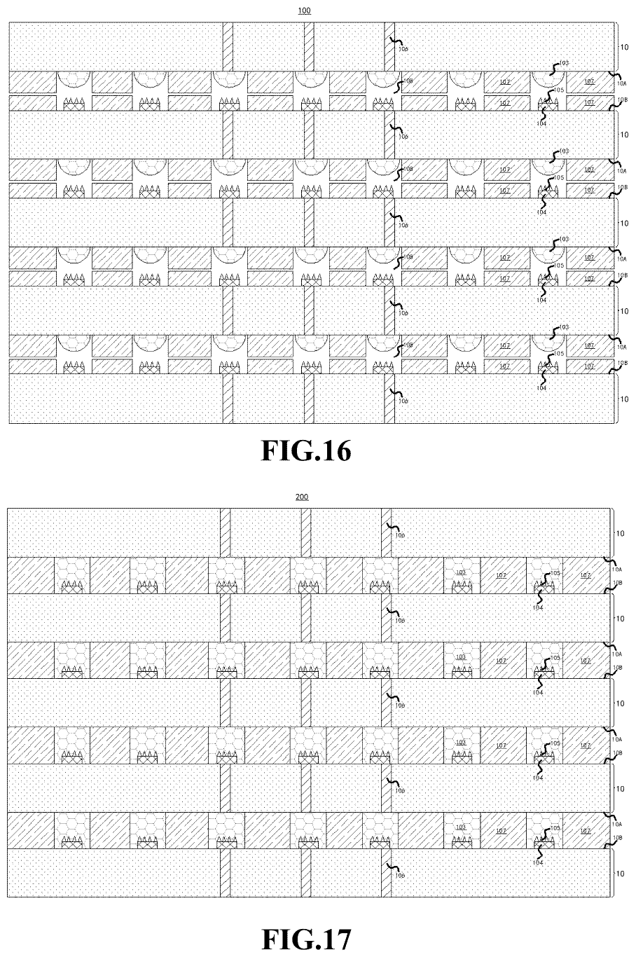

Step 1: preparing TSVs inside the chip of the wafer and performing metal filling, preparing a metal redistribution layer on the second surface of the chip, thinning the wafer, exposing structures such as TSVs, fabricating a redistribution layer on the first surface of the chip, functional conductive pins, non-functional thermal pins and other pin layers to obtain the chip structure having TSVs 106 as shown in FIG. 8, wherein the metal redistribution layer and pin layers are not shown in the drawings;
Step 2: preparing a layer of photoresist at the first surface of the chip, and exposing the preparing positions of the solder balls by exposure and development processes to obtain the chip structure having TSVs 106 and multiple solder preparing positions 102 separated by photoresist 101 as shown in FIG. 3;
Step 3: preparing the solder balls on the first surface of the chip by an electroplating process to obtain a chip structure having TSVs 106 and solder balls 103 separated by photoresist 101 as shown in FIG. 4;
Step 4: removing the photoresist on the first surface of the chip through the PR striping process to obtain the chip structure having TSVs 106 and spaced solder balls 103 as shown in FIG. 5;
Step 5: preparing a layer of negative photoresist at the first surface of the chip to obtain a chip structure having TSVs 106 and solder balls 103 covered by the negative photoresist 107 as shown in FIG. 9;
Step 6: exposing the solder balls on the first surface of the chip by the exposure and development processes to obtain a chip structure having TSVs 106 and solder balls 103 separated by negative photoresist 107 as shown in FIG. 10, wherein the negative photoresist 107 is a semi-cured organic film, which fills the gaps between the solder balls 103;
Step 7: repeating the steps 1 and 2 to expose the preparing position of the metal bumps, and then preparing the metal bumps and the prickles on the metal bumps at the second surface of the chip by processes such as electroplating and chemical plating, specifically, preparing the copper metal bumps by electroplating, then preparing nano-copper wires on the copper metal bumps by electroplating, then electroplating a layer of palladium or gold on the copper wires and the copper metal surface and side walls, and performing a passivation treatment, thereby preparing the second conductive structures with a metal protective film and an inert metal passivation layer to obtain a chip structure having TSVs 106, the solder balls 103 at the first surface 10A and separated by negative photoresist 107, and the metal bumps 104 with the prickles 105 at the second surface 10B and separated by the photoresist 101 as shown in FIG. 11;
Step 8: removing the photoresist on the first surface of the chip through the PR striping process to obtain a chip structure having the TSVs 106, the solder balls 103 at the first surface 10A and separated by the negative photoresist 107, and the spaced metal bumps 104 with the prickles 105 at the second surface 10B as shown in FIG. 12;
Step 9: preparing a layer of negative photoresist at the second surface of the chip to obtain a chip structure having the TSVs 106, the solder balls 103 at the first surface 10A and separated by the negative photoresist 107, and the metal bumps 104 having prickles 105 at the second surface 10B and covered by the negative photoresist 107 as shown in FIG. 13;
Step 10: exposing the metal bumps and the prickles at the second surface of the chip by the exposure and development processes to obtain a chip structure having the TSVs 106, the solder balls 103 at the first surface 10A and separated by the negative photoresist 107, and the metal bumps 104 having prickles 105 at the second surface 10B and sparated by the negative photoresist 107 as shown in FIG. 14;
Step 11: preprocessing the chip structure prepared in the step S10 using heated formic acid, and then fixing the upper-layer chip to the lower-layer chip by the solder balls of the upper-layer chip and the metal bumps with the prickles of the lower-layer chip using pick and place methods in a vacuum environment to obtain a chip stacking structure as shown in FIG. 15, wherein the solder balls 103 of the upper-layer chip 10 are fixed on the metal bump 104 having prickles 105 of the lower-layer chip as shown in FIG. 15;
Step 12: realizing the stacking of multi-layer chip by repeating the above process from the step 1 to the step 11 to obtain a multi-layer chip stacking structure 100 as shown in FIG. 16, and as shown in FIG. 16, in this structure, only temporary bonding of the upper-layer and lower-layer chips is realized, but there is still a gap 108 and the bonding is not complete; and
Step 13: by processes such as vacuuming and reflow, completely bonding the solder of the upper-layer chip to the metal bumps of the lower-layer chip, and heating and curing the organic film to obtain a three-dimensional chip stacking structure 200 as shown in FIG. 17, and as shown in FIG. 17, in this structure, after vacuuming and reflow, the solder diffuses and fills the gaps formed between the organic films, wherein the solder of the upper-layer chip is completely bonded to the metal bumps of the lower-layer chip, and the organic film on the first surface of the upper-layer chip is completely bonded to the organic film on the second surface of the lower-layer chip to form a stably interconnected three-dimensional chip stacking structure.

### Example 2

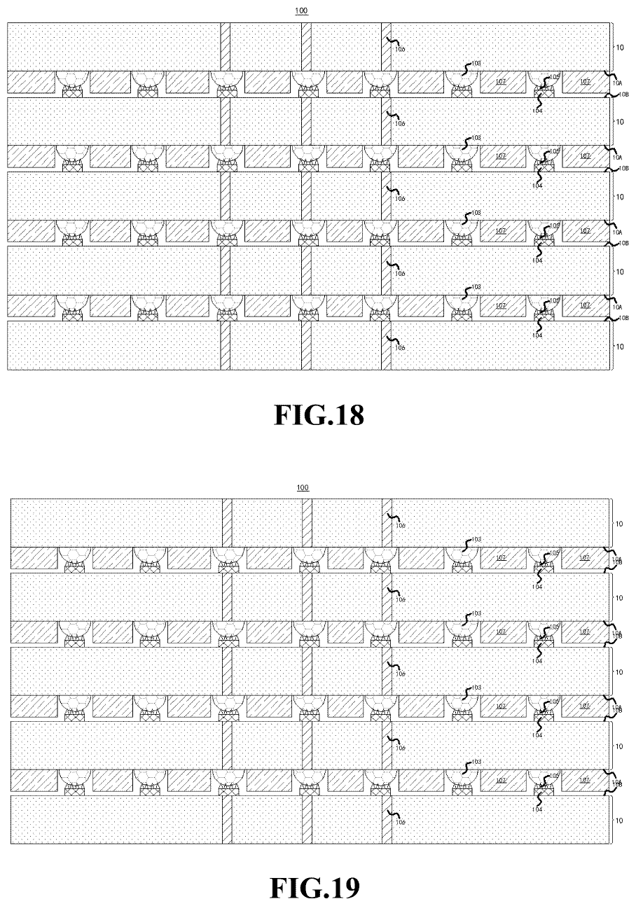

Steps 1-8: Same as the steps 1-8 in the example 1;
Step 9: preprocessing using heated formic acid, and then fixing the upper-layer chip to the lower-layer chip by the solder balls of the upper-layer chip and the metal bumps with the prickles of the lower-layer chip using pick and place methods in a vacuum environment to obtain the chip stacking structure having upper-layer and lower-layer chip as shown in FIG. 18, and as shown in FIG. 18, its structure is different from the structure shown in FIG. 15 in that in this embodiment, there is no organic film barrier wall prepared around the metal bumps at the second surface of the chip, that is, the metal bumps are not isolated by the organic film, and the organic film barrier wall is prepared only at the gap between the solder balls at the first surface;
Step 10: realizing the stacking of multi-layer chip by repeating the process of the steps 1 to 9 above to obtain a multi-layer chip stacking structure 100 as shown in FIG. 19, and as shown in FIG. 19, in this structure, only temporary bonding of the upper-layer and lower-layer chips is realized, but there is still a gap 108 and the bonding is not complete, and because there is no organic film prepared on the second surface, the organic film on the first surface cannot be adhered to the second surface of the lower-layer chip before vacuum reflow; and
Step 11: same as the step 13 of the example 1, wherein the only difference from the example 1 is that in this example, since there is no organic film prepared on the second surface, after vacuum reflow, the organic film on the first surface is directly bonded to the second surface of the lower-layer chip to realize the adhering between the chips.

### Example 3

Steps 1-4: same as the steps 1-4 in the example 1;

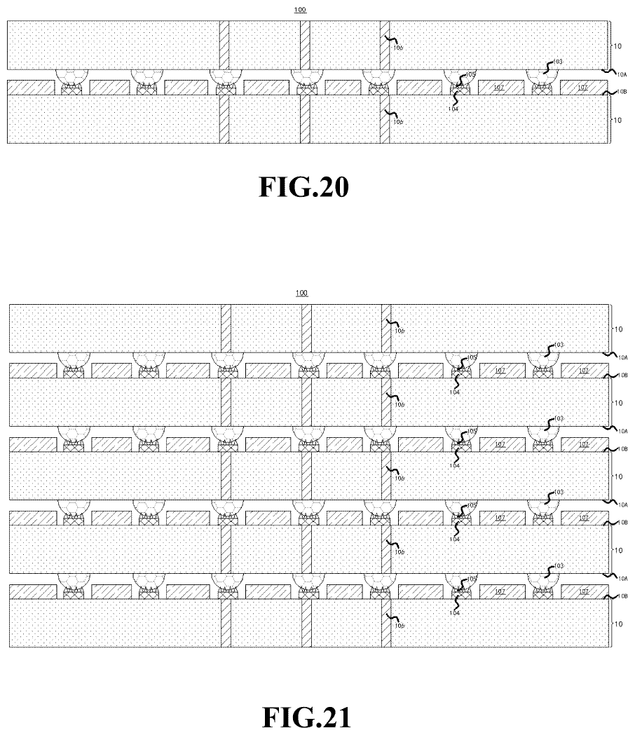

Steps 5-8: same as the steps 7-10 in the example 1;
Step 9: preprocessing the chip using the heated formic acid, and then use pick and place methods in a vacuum environment to fix the upper-layer chip on the lower-layer chip by the solder balls of the upper-layer chip and the metal bumps with the prickles of the lower-layer chip to obtain a chip stacking structure having upper-layer and lower-layer chips 10 as shown in FIG. 20, and as shown in FIG. 20, its structure is different from the structure shown in FIG. 21 in that in this embodiment, there is no organic film barrier wall prepared around the solder balls on the first surface of the chip, and the organic film barrier wall is prepared only at the gap between the metal bumps on the second surface;
Step 10: realizing the stacking of multi-layer chip by repeating the process of the steps 1 to 9 above to obtain a multi-layer chip stacking structure 100 as shown in FIG. 21, and as shown in FIG. 21, in this structure, only temporary bonding of the upper-layer and lower-layer chips is realized but there is still a gap 108 and the bonding is not complete, and because there is no organic film prepared on the first surface, the organic film on the second surface cannot be adhered to the first surface of the lower-layer chip before vacuum reflow; and
Step 11: same as the step 13 of embodiment 1, wherein the only difference from embodiment 1 is that in this example, since there is no organic film prepared on the first surface, after vacuum reflow, the organic film on the second surface is directly bonded to the first surface of the upper-layer chip to realize the adhering between the chips.

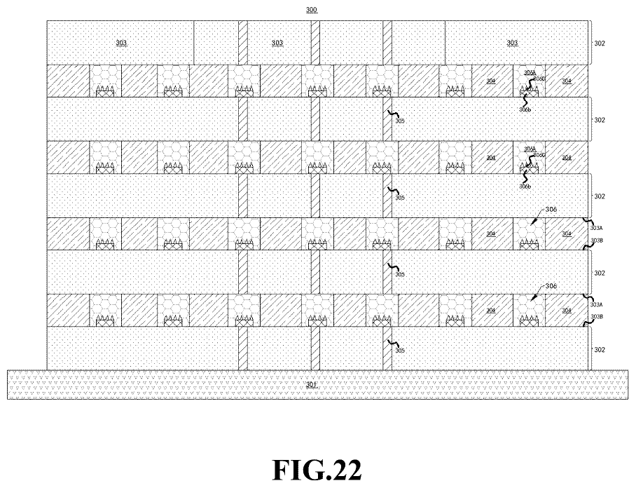

FIG. 22 schematically illustrates a vertical cross-sectional view of a three-dimensional chip stacking structure 300 according to an embodiment of the present invention. As shown in FIG. 22, it includes a substrate 301, at least two chip layers 302 located on the substrate, at least two bonding structures 306 between the adjacent chip layers 302, and an organic film 304 between the adjacent chip layers 302 for adhering the adjacent chip layers 302. The organic film 304 isolates the adjacent bonding structures 306 from each other. Each chip layer 302 includes at least one chip 303. Each chip is provided with TSVs 305 that penetrate the chip. The first surface 303A and the second surface 303B of each chip 303 are electrically connected through the TSVs that penetrate the chip. Among them, the first surface 303A refers to the surface of the chip or chip layer provided with the first conductive structures, and the second surface 303B refers to the surface of the chip or chip layer provided with the second conductive structures. The bonding structures are formed by bonding the first conductive structures of the first surface of the chip in the upper-layer chip and the second conductive structures on the second surface of the chip in the lower-layer chip. Preferably, the second conductive structures are metal bumps having prickles, and the organic film is formed by heating the semi-cured organic film to fully cure. Preferably, the organic film is made of a composite material or a single material of polyimide, photoresist or epoxy prepared by a dry film method or a coating method. The thickness of the organic film can be between 2-50 μm.

In some possible embodiments, the material of the first conductive structures may be soft gold, indium, gallium, tin, tin-silver, tin-gold, other metals or alloys of the above material. Using soft metals or alloys to prepare the first conductive structures makes it easier for the first conductive structures to be inserted and fixed on the prickles of the second conductive structures, and it is easier to realize temporary bonding between the chips.

In other possible embodiments, the material of the first conductive structures may also be nano-scale to micron-scale solder. In other possible embodiments, the material of the first conductive structures may also be nano-scale to micron-scale linear or granular conductive porous dielectric materials of metals such as copper, silver, gold, or tin. Using such metals or alloys to prepare the first conductive structures makes it easier for the first conductive structures to be inserted and fixed on the prickles of the second conductive structures, and it is easier to realize temporary bonding between the chips. More preferably, nano-scale particles or mixed nano-scale and micro-scale particles also have the characteristic of low melting point (nanoparticles have low melting point). Using materials with such characteristic to prepare the first conductive structures also makes it easier for the first conductive structures to realize complete bonding with the second conductive structures during reflow soldering, and further reduces the implement difficulty of interlayer bonding process.

In some possible embodiments, the material of the metal bumps of the second conductive structures is copper, nickel, gold, silver and other metals or alloys of the above material, and the material of the prickles of the second conductive structures is selected from metals such as nickel, copper, gold, or silver. In other embodiments, the material of the second conductive structures can also be selected from other metals or alloys as long as its hardness is higher than that of the first conductive structures, so that it is easier for the first conductive structures to be inserted and fixed on the prickles of the second conductive structures, and it is easier to realize temporary bonding between the chips.

As a possible embodiment, the height of the metal bumps is between 0.5 μm and 50 μm, and the height of the prickles is between 0.05 μm and 10 μm.

In a preferred embodiment, the surface and the side walls of the metal bumps are further prepared with a layer of metal protective film to passivate the metal bumps and prevent them from oxidizing, thereby improving the reliability of the three-dimensional chip stacking structure. The metal used in the metal protective film can be metals such as silver, gold, nickel, or palladium. Preferably, the metal used in the metal protective film is a metal different from the material of the metal bumps.

As a possible embodiment, the prickles on the metal bumps of the second conductive structures are formed by chemical or physical deposition. In a preferred embodiment, the surface of the prickles can also be plated with a passivation layer of inert metal such as palladium or gold to protect the prickles and prevent them from oxidizing. As a preferred embodiment, the prickles can be formed as metallic linear, rod-shaped, cone or other shaped clusters, and a diameter of the smallest unit forming the cluster is nano-scale to micron-scale. This allows the prickles to be more easily and firmly inserted into the first conductive structures, making the temporary bonding process easier to implement.

The three-dimensional chip stacking structure of the embodiment of the present invention is easy to prepare, has low packaging cost, and has higher yield and reliability. Therefore, it can be widely used in high-performance memory, high-capacity memory, high-bandwidth memory, etc.

It should be noted that the number of chips in each layer of chip layers can be selected according to needs and expectations. Each chip can be a chip that realizes the same function, or it can be a chip that realizes different functions. Each of the chips can be a chip on a wafer or it can also be an independent chip cut from a wafer, which is not limited in the embodiment of the present invention. In addition, in specific applications, the number of the first conductive structures, the TSVs and the second conductive structures can also be set according to needs and expectations. In specific applications, the first surface and the second surface of the chip can also be formed with a redistribution layer according to needs. The number of redistribution layers can be designed according to needs and expectations. In some embodiments, the first surface of the chip can also be formed with a pin layer according to needs.

As a preferred embodiment, the three-dimensional chip stacking structure shown in FIG. 22 can be manufactured by the method of any one of the previous examples.

Finally, it should be noted that the above embodiments are only used to illustrate the technical solution of the present application, but not to limit it; although the present application has been described in detail with reference to the foregoing embodiments, a person having ordinary skill in the art should understand that the technical solutions described in the foregoing embodiments may be modified or some of the technical features may be replaced by equivalent ones; however, such modifications or replacements do not cause the essence of the corresponding technical solutions to deviate from the spirit and scope of the technical solutions in the embodiments of the present application.

What is claimed is:

1. A three-dimensional chip stack preparing method, characterized by comprising:
forming a conductive structure at a first surface and a second surface of a chip prepared with a TSV and a redistribution layer, wherein the conductive structure comprises a first conductive structure at the first surface of the chip and a second conductive structure at the second surface of the chip, the second conductive structure is a metal bump having prickles;
preparing a semi-cured organic film at the first surface and/or the second surface of the chip, and opening a window on the semi-cured organic film to expose the first conductive structure and/or the second conductive structure;
completing a multi-layer chip stack by sequentially fixing the first conductive structure of an upper-layer chip to the prickles of the second conductive structure of a lower-layer chip;
applying pressure to a top portion of the stacked multi-layer chip, and immersing a side wall of the metal bump and the prickles of the second conductive structure together with the first conductive structure, by means of a vacuum reflow process, to realize a complete bonding of the first conductive structure and the second conductive structure, wherein the second conductive structure is in the lower-layer chip and the first conductive structure is in the upper-layer chip of the stacked multi-layer chip, and adhering the upper-layer and lower-layer chips by the semi-cured organic film; and
heating the organic film to fully cure the organic film to form a three-dimensional chip stacking structure.

2. The method as claimed in claim 1, wherein the material of the first conductive structure is soft gold, indium, gallium, tin, tin-silver, tin-gold, other metals or alloys of the above material;
or the material of the first conductive structure is nano-scale to micron-scale solder;
or the material of the first conductive structure is nano-scale to micron-scale linear or granular conductive porous dielectric materials of copper, silver, gold, tin or other metals.

3. The method as claimed in claim 1, wherein the material of the metal bump of the second conductive structure is copper, nickel, gold, silver, or alloys of the above material; and a height of the metal bump is between 0.5 μm and 50 μm.

4. The method as claimed in claim 3, wherein the surface and the side wall of the metal bump are further prepared with a metal protective film, the metal used in the metal protective film is silver, gold, nickel or palladium, and the metal used in the metal protective film is different from the material of the metal bump.

5. The method as claimed in claim 1, wherein the prickles on the metal bump of the second conductive structure are formed by chemical or physical deposition;
the material of the prickles is selected from nickel, copper, gold or silver; and a height of the prickles is between 0.05 μm and 10 μm.

6. The method as claimed in claim 5, wherein a surface of the prickles is further plated with an inert metal passivation layer; and
the prickles are linear, rod-shaped, cone or other shaped clusters, a diameter of a smallest unit forming the cluster is nano-scale to micron-scale.

7. The method as claimed in claim 1, wherein the organic film is a negative photoresist, the negative photoresist is made of a composite material or a single material of polyimide, photoresist or epoxy prepared by a dry film method or a coating method.

8. The method as claimed in claim 1, wherein said adhering the upper-layer and lower-layer chips by the semi-cured organic film comprises:
in the case that the semi-cured organic film is prepared only at a gap of the first conductive structure, adhering the semi-cured organic film at the gap of the first conductive structure of the upper-layer chip to the second surface of the lower-layer chip after vacuum reflow to realize the adhering of the upper-layer and lower-layer chips;
in the case that the semi-cured organic film is prepared only at a gap of the second conductive structure, adhering the semi-cured organic film at the gap of the second conductive structure of the lower-layer chip to the first surface of the upper-layer chip after vacuum reflow to realize the adhering of the upper-layer and lower-layer chips;
in the case that the semi-cured organic film is prepared at the gap of the first conductive structure and the gap of the second conductive structure, adhering the semi-cured organic film at the gap of the first conductive structure of the upper-layer chip to the semi-cured organic film at the gap of the second conductive structure of the lower-layer chip after vacuum reflow to realize the adhering of the upper-layer and lower-layer chips.

9. The method as claimed in claim 1, wherein prior to said fixing the first conductive structure of an upper-layer chip to the prickles of the second conductive structure of a lower-layer chip further comprises:
preprocessing the chip using the heated formic acid.

10. The method as claimed in claim 1, wherein the first conductive structure of an upper-layer chip is fixed on the prickles of the second conductive structure of a lower-layer chip by a pick-and-place process.

11. A use of the method as claimed in claim 1 on a chip-level stack or a wafer-level stack.

12. A three-dimensional chip stacking structure, characterized by comprising:
a substrate;
at least two chip layers provided on the substrate, each of the chip layers comprising at least one chip;
at least two bonding structures provided between the adjacent chip layers, wherein the boding structures are formed by bonding a first conductive structure of a first surface of the chip in the upper-layer chip and a second conductive structure of a second surface of the chip in the lower-layer chip, the second conductive structure is a metal bump having prickles;
an organic film provided between the adjacent chip layers for adhering the adjacent chip layers, the organic film isolating the adjacent bonding structures from each other, wherein the organic film is formed by heating the semi-cured organic film to fully cure; and
a TSV penetrating the chip in the chip layer, the first surface and the second surface of each chip being connected by the TSV penetrating the chip.

13. The three-dimensional chip stacking structure as claimed in claim 12, wherein the material of the first conductive structure is soft gold, indium, gallium, tin, tin-silver, tin-gold, other metals or alloys of the above material;
or the material of the first conductive structure is nano-scale to micron-scale solder;
or the material of the first conductive structure is nano-scale to micron-scale linear or granular conductive porous dielectric materials of copper, silver, gold, tin or other metals.

14. The three-dimensional chip stacking structure as claimed in claim 12, wherein the material of the metal bump of the second conductive structure is copper, nickel, gold, silver, or alloys of the above material; and a height of the metal bump is between 0.5 μm and 50 μm.

15. The three-dimensional chip stacking structure as claimed in claim 12, wherein the surface and the side wall of the metal bump are further prepared with a metal protective film, the metal used in the metal protective film is silver, gold, nickel or palladium, and the metal used in the metal protective film is different from the material of the metal bump.

16. The three-dimensional chip stacking structure as claimed in claim 12, wherein the prickles on the metal bump of the second conductive structure are formed by chemical or physical deposition;
the material of the prickles is selected from nickel, copper, gold or silver; and a height of the prickles is between 0.05 μm and 10 μm.

17. The three-dimensional chip stacking structure as claimed in claim 12, wherein a surface of the prickles is further plated with an inert metal passivation layer; and
the prickles are linear, rod-shaped, cone or other shaped clusters, a diameter of a smallest unit forming the cluster is nano-scale to micron-scale.

18. The three-dimensional chip stacking structure as claimed in claim 12, wherein the organic film is a negative photoresist, the negative photoresist is made of a composite material or a single material of polyimide, photoresist or epoxy prepared by a dry film method or a coating method.

19. The three-dimensional chip stacking structure as claimed in claim 12, wherein the three-dimensional chip stacking structure is a chip-level stack or a wafer-level stack.

20. A three-dimensional chip stacking structure, characterized by being manufactured by the method as claimed in claim 1.
